(19) United States
(12) Patent Application Publication
(10) Pub. No.: US 2009/0108351 A1
(43) Pub. Date: Apr. 30, 2009

(54) FINFET MEMORY DEVICE WITH DUAL SEPARATE GATES AND METHOD OF OPERATION

(75) Inventors: Haining S. Yang, Wappingers Falls, NY (US); Robert C. Wong, Poughkeepsie, NY (US); Huilong Zhu, Poughkeepsie, NY (US)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 11/925,177

(22) Filed: Oct. 26, 2007

(51) Int. Cl. H01L 29/786; H01L 27/12

(52) U.S. Cl. 257/347; 257/E29.275; 257/E27.112

(57) ABSTRACT

A FinFET device comprises a front gate (FG) and a separate back gate (BG) disposed on opposite sides of the fine. The fin structure may act as a floating body of a volatile memory cell. The front and back gates may be doped with the same or opposite polarity, and may be biased oppositely. A plurality of FinFETs may be connected in a memory array with single column erase, or double column erase capability.

### TECHNICAL FIELD

The invention relates to the structure and operation of semiconductor memory cells, and more particularly to FinFET memory devices (or cells).

### BACKGROUND ART

### The Field Effect Transistor

The transistor is a solid state semiconductor device which can be used for amplification, switching, voltage stabilization, signal modulation and many other functions. Generally, a transistor has three terminals, and a voltage applied to a specific one of the terminals controls current flowing between the other two terminals.

The terminals of a field effect transistor (FET) are commonly named source, gate and drain. In the FET, a small amount of voltage is applied to the gate in order to control current flowing between the source and drain. In FETs, the main current appears in a narrow conducting channel formed near (usually primarily under) the gate. This channel connects electrons from the source terminal to the drain terminal. The channel conductivity can be altered by varying the voltage applied to the gate terminal, enlarging or constricting the channel and thereby controlling the current flowing between the source and the drain.

The terminals of a field effect transistor (FET) are commonly named source, gate and drain. In the FET, a small amount of voltage is applied to the gate in order to control current flowing between the source and drain. In FETs, the main current appears in a narrow conducting channel formed near (usually primarily under) the gate. This channel connects electrons from the source terminal to the drain terminal. The channel conductivity can be altered by varying the voltage applied to the gate terminal, enlarging or constricting the channel and thereby controlling the current flowing between the source and the drain.

FIG. 1 illustrates a FET 100 comprising a p-type substrate (or a p-well in the substrate), and two spaced-apart n-type diffusion areas—one of which will serve as the “source”, the other of which will serve as the “drain” of the transistor. The space between the two diffusion areas is the “channel”. A thin dielectric layer is disposed on the substrate above the channel, and a “gate” structure is disposed over the dielectric layer, thus also atop the channel. (The dielectric under the gate is also commonly referred to as “gate oxide” or “gate dielectric”).

Electrical connections (not shown) may be made to the source, the drain, and the gate. The substrate may be grounded. Generally, when there is no voltage on the gate, there is no electrical conduction (connection) between the source and the drain. As voltage (of the correct polarity) applied to the gate, there is a “field effect” in the channel between the source and the drain, and current can flow between the source and the drain, and can be controlled by the voltage applied to the gate. In this manner, a small signal (gate voltage) can control a relatively large signal (current flow between the source and the drain).

The FET is exemplary of a MOSFET (metal oxide semiconductor FET) transistor. With the specified “n” and “p” types shown above, an “n-channel MOSFET” can be formed. With opposite polarities (swapping “p” for “n” in the diffusions, and “n” for “p” in the substrate or well), a p-channel FET can be formed. In CMOS (complementary metal oxide semiconductor), both n-channel and p-channel MOS transistors are used, often paired with one another.

### Multigate Devices

A multigate device or Multigate Field Effect Transistor (MuGFET) refers to a MOSFET which incorporates more than one gate in a single device. The multiple gates may be controlled by a single gate electrode, wherein the multiple gate surfaces act electrically as a single gate, or by independent gate electrodes. A multigate device employing independent gate electrodes is sometimes called a Multiple Independent Gate Field Effect Transistor or MIGFET.

Multigate transistors are one of several strategies being developed by CMOS semiconductor manufacturers to create ever-smaller microprocessors and memory cells. The primary roadblock to widespread implementation is manufacturability, as both planar and non-planar designs present significant challenges, especially with respect to lithography and patterning.

### Planar Double Gate Transistors

Planar double-gate transistors employ conventional planar (layer by layer) manufacturing processes to create double-gate devices, avoiding more stringent lithography requirements associated with non-planar, vertical transistor structures. In planar double-gate transistors, the channel is sandwiched between two independently fabricated gate/gate oxide stacks. The primary challenge in fabricating such structures is achieving satisfactory self-alignment between the upper and lower gates.

### FinFETs

The term FinFET was coined by University of California, Berkeley researchers to describe a nonplanar, double-gate transistor built on an SOI substrate, based on the earlier DELTA (single-gate) transistor design. The distinguishing characteristic of the FinFET is that the conducting channel (gate) is wrapped around a thin silicon “fin”, which forms the body of the device. The dimensions of the fin determine the effective channel length of the device.

In current usage, the term FinFET has a less precise definition. Among microprocessor manufacturers, AMD, IBM, and Motorola describe their double-gate development efforts as FinFET development whereas Intel avoids using the term to describe their closely related tri-gate architecture. In the technical literature, FinFET is used somewhat generically to describe any fin-based, multigate transistor architecture regardless of number of gates.

FIG. 2A illustrates a double-gate FinFET device 200. The FinFET device 200 is essentially a silicon on insulator (SOI) device, and may be fabricated using conventional SOI fabrication processes.

Generally, a silicon “fin”, which forms the body of the device, comprises an elongate (long and narrow) polysilicon structure disposed on the surface of the substrate. The two ends of the fin may be enlarged, one end serving as the “source”, the other end serving as the “drain” of the device. A channel is defined between the source and drain.

An elongate gate structure is disposed approximately halfway along the length of the fin (approximately midway between the source and drain), and extends transverse to the fin, resulting in a portion of the gate being disposed on a one side of the fin, and another portion of the gate being disposed on the opposite side of the fin. The gate structure also extends over, wraps around, or “straddles” the fin, so the two portions of the gate structure are contiguous with one another. The substrate itself serves as the “second” gate in this double-gate FinFET device 200.

There is a thin layer of oxide (not shown) between the gate structure and the fin, serving the purpose of a gate oxide, as discussed above with regard to the FET of FIG. 1. There may be dielectric material, such as buried oxide (BOX, not shown) on the substrate, under the gate, as well as under the source and drain, generally to electrically isolate the device from the substrate. Electrical connections (not shown) may be made to the source, the drain, and the gate. The substrate may be grounded.

As best shown in FIG. 2B, a layer of oxide 204, such as buried oxide (BOX) having a thickness of 500-1000 Å (Angstroms) is disposed on a silicon substrate 202. A silicon layer (or SOI layer) is disposed on top of BOX 204 using wafer bonding technique. Other processes such as separation by implanted oxygen (SIMOX) can also be used to form an SOI wafer.

A silicon fin 210 is defined using a etching process on the SOI layer atop the BOX 204. The fin 210 may be an elongate (long, thin) structure, with a generally rectangular cross-section, having two opposite side surfaces 212a and 212b, a top edge surface 212c, and a bottom edge surface 212d opposite the top edge surface 212c. The fin 210 may have a width dimension “W” (as measured between its two side surfaces) of approximately 20-60 nm, and a height dimension “H” (as measure between its top and bottom edge surfaces) of approximately 30-100 nm.

The fin 210 may be surrounded by a thin layer 214 of oxide, such as thermal oxide or a high K dielectric layer such as an HfO2 layer. The oxide 214 may cover the top edge surface 212c, and two side surfaces 212a, 212b of the fin 210. The oxide 214 may have a thickness of approximately 1-3 nm.

The fin 210 may be doped to have a first polarity, such as P− for a N-type transistor, and N− for a P-type transistor.

A gate structure 220 is formed as a generally inverted U-Shaped structure which has a portion which extends over, or “straddles” the fin 210.

A first portion 222a of the gate structure 220 extends vertically (as shown) down one side surface 212a of the fin 210, to the BOX layer 204. A second portion 222b of the gate structure 220 extends vertically down the opposite side surface 212b of the fin 210, then across the BOX layer 204, away from the fin 210. A third portion 222c of the gate structure 220 is disposed atop the top edge surface 212c of the fin 210, extends horizontally (as shown) and joins a top of the first portion 222a of the gate structure 220 with a top of the second portion 220b of the gate structure. The three portions 222a, 222b, 222c are contiguous (continuous, formed integrally with one another).

A first “leg” portion 222d of the gate structure 220 extends from a bottom region of the first portion 222a, horizontally, away from the fin 210, on the BOX layer 204. A second “leg” portion 222e of the gate structure 220 extends from a bottom region of the second portion 222b, horizontally, away from the fin 210, on the BOX layer 204. The horizontal leg portions of the gate structure can be used as a contact region.

The gate structure 220 may have a thickness of approximately 70-100 nm. The gate structure 220 may be formed of polycrystalline silicon, and may be doped to have a polarity, such as N+ for N-type transistor and P+ for P-type transistor. Also, a metallic material such as TiN can be used as a gate.

The gate structure 220 serves as one gate of the double-gate FinFET device 200. The substrate itself serves as the “second” gate in this double-gate FinFET device 200. In this role, the substrate may be referred to as the “back gate”. This has some inherent limitations. For example, the substrate has to be biased to some voltage to keep the device operational. The effectiveness of the substrate as a back gate is limited, because the BOX is very thick, approximately 1000 Å, typically at least 500 Å. It is therefore difficult to control the P-body (the fin) across the BOX. Large voltages are required. Also, control over single devices is difficult because the substrate is shared by all of the devices on the wafer. For example, when manipulating the substrate voltage to erase a given FinFET, you may erase the entire wafer. Therefore, a selective erase is not readily achieved.

U.S. Pat. No. 7,037,790, incorporated by reference in its entirety herein, discloses independently accessed double-gate and tri-gate transistors in same process flow. As noted therein,
Independently-controlled double-gate (I-gate) transistors are a relatively recent development in semiconductor processing. They have two gates disposed on opposite sides of a channel, each gate capable of being independently controlled. This provides added transistor flexibility and enables, for example, using a single body to form a dynamic random-access memory (DRAM) cell. Tri-gate transistors are another relatively recent development in semiconductor processing. With tri-gate transistors, the gate forms adjacent three sides of a channel region. Tri-gate transistors, particularly when used with a high-k insulator and metal gate, can substantially improve the speed and performance of integrated circuits.

As noted in the article entitled “Retention Characteristics of Zero-capacitor RAM (Z-RAM) cell based on FinFET and Tri-Gate devices”, Nagoga et al., 2005 IEEE International SOI Conference, 0-7803-9212-4/05, copr. 2005, IEEE,
Manufacturers of Dynamic Random Access Memory (DRAM) and embedded DRAM (eDRAM) have a tremendous challenge to shrink the memory cell and the main issue in cell area reduction lies with the capacitor integration. In the recently introduced zero-capacitor floating body memory cell (Z-RAM), the conventional storage capacitor is replaced by the body capacitance of a SOI MOSFET. The charge stored in the floating body affects the device threshold voltage through the body effect and can be used to distinguish two states. The functionality of a Z-RAM memory array was already demonstrated on silicon using PD or FD SOI devices. To ensure the scalability of this new memory, it is mandatory to demonstrate its operation on advanced devices such as double-gate MOSFETs, FinFETs, etc. Recently TCAD simulations were used to illustrate the memory effect in double-gate FinFET devices.
   Normally the FinFET's body is fully depleted. By applying a negative voltage (Vbg) to the back gate, an accumulation layer can be created at the back interface. In this case, the transistor shows a partially depleted behavior and can be used as a memory cell. In a Z-RAM cell the state “1” corresponds to an excess of majority carriers in the transistor's body and the state “0” corresponds to their deficiency. The sensing is performed by measuring the channel current.

### DRAM, and Memory Array Architecture Generally

Dynamic random access memory (DRAM) is a type of random access memory that usually stores data as electrical charges in a capacitor structure associated with a transistor. Since capacitors leak charge (generally, a capacitor is only useful for temporarily storing an electrical charge), the information (data) eventually fades unless the capacitor charge is refreshed (read, and re-written) periodically, such as every 64 ms (milliseconds). DRAM is usually arranged in a square array of one capacitor and transistor per cell.

Memory arrays are well known, and comprise a plurality (many, including many millions) of memory cells organized (including physically arranged) in rows (usually represented in drawings as going across the page, horizontally, from left-to-right) and columns (usually represented in drawings as going up and down the page, from top-to-bottom).

FIG. 3 illustrates an array of DRAM cells (labeled “a” through “i”) connected to a number of word lines (WL) and bit lines (BL). (Each DRAM cell is shown as comprising a FET and a capacitor.) For example, in the memory cell “e”, the FET has its gate connected to WL(n), its source is connected to BL(n), and its drain connected to a capacitor. The nine memory cells (“a” through “i”) illustrated in FIG. 3 are exemplary of many millions of memory cells that may be resident on a single chip.

The gates of the FETs in memory cells “a”, “b” and “c” are all connected to the same word line WL(n−1), the gates of the FETs in memory cells “d”, “e” and “f” are all connected to the same word line WL(n), and the gates of the FETs in memory cells “g”, “h” and “i” are all connected to the same word line WL(N+1). Thus, a voltage applied to a given word line (WL) can affect many memory cells—namely all the memory cells connected to that word line.

Similarly, the sources of the FETs in memory cells “a”, “d” and “g” are all connected to the same bit line BL(n−1), the sources of the FETs in memory cells “b”, “e” and “h” are all connected to the same bit line BL(n), and the sources of the FETs in memory cells “c”, “f” and “i” are all connected to the same bit line BL(n+1). Thus, a voltage applied to a given bit line (BL) can affect many memory cells—namely all the memory cells connected to that word line.

### Prior Art References

The following references are incorporated by reference in their entirety:

U.S. Pat. No. 7,037,790

“A Capacitorless Double Gate DRAM Technology for Sub-100-nm Embedded and Stand-alone Memory Applications”, Kuo et al., IEEE Transactions on Electron Devices, Vol. 50, No. 12, December 2003.

“Retention Characteristics of Zero-capacitor RAM (Z-RAM) cell based on FinFET and Tri-Gate devices”, Nagoga et al., 2005 IEEE International SOI Conference, 0-7803-9212-4/05, copr. 2005, IEEE.

“Design of a 128-Mb SOI DRAM Using the Floating Body Cell (FBC)”, Ohsawa et al., IEEE Journal of Solid-State Circuits, Vol. 41, No. 1, January 2006.

“Fully-Depleted FBC (Floating Body Cell) with enlarged signal Window and Excellent Logic Process Compatibility”, Shino et al., International Electronic Device Meeting, 0-7803-8684-1/04, copr. 2004, IEEE.

“Memory Design Using a One-Transistor Gain Cell on SOI”, Ohsawa et al., IEEE Journal of Solid-State Circuits, Vol. 37, No. 11, November 2002.

### GLOSSARY

Unless otherwise noted, or as may be evident from the context of their usage, any terms, abbreviations, acronyms or scientific symbols and notations used herein are to be given their ordinary meaning in the technical discipline to which the disclosure most nearly pertains. The following terms, abbreviations and acronyms may be used throughout the descriptions presented herein and should generally be given the following meaning unless contradicted or elaborated upon by other descriptions set forth herein. Some of the terms set forth below may be registered trademarks (®).
Anisotropic literally, one directional. An example of an anisotropic process is sunbathing. Only surfaces of the body exposed to the sun become tanned. (see “isotropic”).
bit The word “bit” is a shortening of the words “binary digit.” A bit refers to a digit in the binary numeral system (base 2). A given bit is either a binary “1” or “0”. For example, the number 1001011 is 7 bits long. The unit is sometimes abbreviated to “b”. Terms for large quantities of bits can be formed using the standard range of prefixes, such as kilobit (Kbit), megabit (Mbit) and gigabit (Gbit). A typical unit of 8 bits is called a Byte, and the basic unit for 128 Bytes to 16K Bytes is treated as a “page”. That is the “mathematical” definition of “bit”. In some cases, the actual (physical) left and right charge storage areas of a NROM cell are conveniently referred to as the left “bit” and the right “bit”, even though they may store more than one binary bit (with MLC, each storage area can store at least two binary bits). The intended meaning of “bit” (mathematical or physical) should be apparent from the context in which it is used.
bit line or bitline (BL). A conductor connected to (or which may actually be) the drain (or source) of a memory cell transistor.
BOX short for buried oxide.
Capacitor A capacitor is an electrical device that can store energy in the electric field between a pair of closely spaced conductors (called “plates”). The process of storing energy in the capacitor is known as “charging”, and involves electric charges of equal magnitude, but opposite polarity, building up on each plate.
Charge carriers “Charge carrier” denotes in physics a free (mobile, unbound) particle carrying an electric charge. In semiconductors, electrons and holes act as charge carriers. The more abundant charge carriers are called majority carriers. In N-type semiconductors they are electrons, while in P-type semiconductors they are holes. The less abundant charge carriers are called minority carriers; in N-type semiconductors they are holes, while in P-type semiconductors they are electrons. Whenever an electron acquires energy sufficient to “move” from the valence band to the conduction band a free hole is created in the valence band, and hence, electron-hole pair is generated. When an electron meets with a hole, they recombine and vanish.
CMOS short for complementary metal oxide semiconductor. CMOS consists of n-channel and p-channel MOS transistors. Due to very low power consumption and dissipation as well minimization of the current in “off” state CMOS is a very effective device configuration for implementation of digital functions. CMOS is a key device in state-of-the-art silicon microelectronics.
   CMOS Inverter: A pair of two complementary transistors (a p-channel and an n-channel) with the source of the n-channel transistor connected to the drain of the p-channel one and the gates connected to each other. The output (drain of the p-channel transistor) is high whenever the input (gate) is low and the other way round. The CMOS inverter is the basic building block of CMOS digital circuits.
      NMOS: n-channel
      CMOS. PMOS: p-channel CMOS.
CMP short for chemical-mechanical polishing. CMP is a process, using both chemicals and abrasives, comparable to lapping, for removing material from a built up structure, resulting in a particularly planar resulting structure.
Dopant an element added to silicon (or another semiconductor) to decrease its resistivity. (Silicon, by itself does not conduct electricity). Dopants are generally categorized as either “p-type” (acceptors) or “n-type” (donors). Common dopants in silicon include: for p-type, boron, B, Indium, In; for n-type phosphorous, P, arsenic, As, antimony, Sb. In common usage, a structure doped with n-type dopants is considered to have an opposite polarity to a structure doped with p-type dopants. The following terminology may be used to specify polarity and concentration of dopant: N+ Heavily doped, N-type silicon (wafer or epitaxial layer) N− Lightly doped N-type silicon (wafer or epitaxial layer) P− Lightly doped P-type silicon (wafer or epitaxial layer) P+ Heavily doped P-type silicon (wafer or epitaxial layer)
DRAM Dynamic RAM (DRAM) is a type of memory cell, generally using a capacitor to store charge and, since the charge tends to leak out, the memory cell must be periodically read and refreshed, “dynamically”.
Erase a method to erase data on a large set of bits in the array, by applying voltage scheme that inject holes or remove electrons in the bit set. This method causes all bits to reach a low Vt level.
FET short for field effect transistor. The FET is a transistor that relies on an electric field to control the shape and hence the conductivity of a “channel” in a semiconductor material. FETs are sometimes used as voltage-controlled resistors. The terminals of FETs are called gate, drain and source.
Flash memory Flash memory is a form of non-volatile memory (EEPROM) that can be electrically erased and reprogrammed. Flash memory architecture allows multiple memory locations to be erased or written in one programming operation.
isotropic literally, identical in all directions. An example of an isotropic process is dissolving a tablet in water. All exposed surfaces of the tablet are uniformly acted upon. (see “anisotropic”)
mask a layer of material which is applied over an underlying layer of material, and patterned to have openings, so that the underlying layer can be processed where there are openings. After processing the underlying layer, the mask may be removed. Common masking materials are photoresist and nitride. Nitride is usually considered to be a “hard mask”.
MLC short for multi-level cell. In the context of a floating gate (FG) memory cell, MLC means that at least two bits of information can be stored in the memory cell.
MOS short for metal oxide semiconductor.
MOSFET short for metal oxide semiconductor field-effect transistor. MOSFET is by far the most common field-effect transistor in both digital and analog circuits. The MOSFET is composed of a channel of n-type or p-type semiconductor material, and is accordingly called an NMOSFET or a PMOSFET. (The ‘metal’ in the name is an anachronism from early chips where gates were metal; modern chips use polysilicon gates, but are still called MOSFETs).
nitride commonly used to refer to silicon nitride (chemical formula Si3N4). A dielectric material commonly used in integrated circuit manufacturing. Forms an excellent mask (barrier) against oxidation of silicon (Si). Nitride is commonly used as a hard mask or, in the case of a NVM memory cell having an ONO layer as a charge-trapping material.
n-type semiconductor in which concentration of electrons is higher than the concentration of “holes”. See p-type.
NVM short for non-volatile memory. NVM is computer memory that can retain the stored information even when not powered. Examples of non-volatile memory include read-only memory, flash memory, most types of magnetic computer storage devices (e.g. hard disks, floppy disk drives, and magnetic tape), optical disc drives, and early computer storage methods such as paper tape and punch cards.
oxide commonly used to refer to silicon dioxide (SiO2). Also known as silica. SiO2 is the most common insulator in semiconductor device technology, particularly in silicon MOS/CMOS where it is used as a gate dielectric (gate oxide); high quality films are obtained by thermal oxidation of silicon. Thermal SiO2 forms a smooth, low-defect interface with Si, and can be also readily deposited by CVD. Some particular applications of oxide are:
   LV Oxide short for low voltage oxide. LV refers to the process used to deposit the oxide.
   HV Oxide short for high voltage oxide. HV refers to the process used to deposit the oxide
   STI Oxide short for shallow trench oxide. Oxide-filled trenches are commonly used to separate one region (or device) of a semiconductor substrate from another region (or device).
Poly short for polycrystalline silicon (Si). Heavily doped poly Si is commonly used as a gate contact in silicon MOS and CMOS devices.
p-type semiconductor in which concentration of “holes” is higher than the concentration of electrons. See n-type. Examples of p-type silicon include silicon doped (enhanced) with boron (B), Indium (In) and the like.
Program a method to program a memory cells, or half cells, typically by applying a voltage scheme that injects electrons to increase the Vt of the cells or half cells being programmed.
PROM short for programmable read-only memory.
RAM short for random access memory. RAM refers to data storage formats and equipment that allow the stored data to be accessed in any order—that is, at random, not just in sequence. In contrast, other types of memory devices (such as magnetic tapes, disks, and drums) can access data on the storage medium only in a predetermined order due to constraints in their mechanical design.
Read a method to read the digital data stored in a memory cell.
Resist short for photoresist. also abbreviated “PR”. Photoresist is often used as a masking material in photolithographic processes to reproduce either a positive or a negative image on a structure, prior to etching (removal of material which is not masked). PR is usually washed off after having served its purpose as a masking material.
ROM short for read-only memory.
Si Silicon, a semiconductor material.
SLC short for single level cell. In the context of a floating gate (FG) memory cell, SLC means that one bit of information can be stored in the memory cell. In the context of an NROM memory cell, SLC means that at least two bits of information can be stored in the memory cell.
SOI short for Silicon-On-Insulator. SOI is basically a silicon wafer with a thin layer of oxide (SiO2) buried in it; devices are built into a layer of silicon on top of the buried oxide; SOI substrates provide superior isolation between adjacent devices in an integrated circuit as compared to devices built into bulk wafers (elimination of “latch-up” in CMOS devices); also, improved performance of SOI devices due to reduced parasitic capacitances.
Spacer a spacer, as the name implies, is a material (such as a layer of oxide) disposed on an element (such as a poly gate electrode). For example, sidewall spacers disposed on sides of a gate electrode cause subsequent implants to occur further away from the gate than otherwise (without the spacers in place).
STI short for shallow trench isolation
Units of Length Various units of length may be used herein, as follows:
   meter (m) A meter is the SI unit of length, slightly longer than a yard. 1 meter=˜39 inches. 1 kilometer (km)=1000 meters=˜0.6 miles. 1,000,000 microns=1 meter. 1,000 millimeters (mm)=1 meter. 100 centimeters (cm)=1 meter.
   micron (μm) one millionth of a meter (0.000001 meter); also referred to as a micrometer.
   mil 1/1000 or 0.001 of an inch; 1 mil=25.4 microns.
   nanometer (nm) one billionth of a meter (0.000000001 meter).
   Angstrom (\acute{Å}) one tenth of a billionth of a meter. 10 \acute{Å}=1 nm.
Voltage abbreviated v, or V. A voltage can be positive or negative (or zero). Usually, a negative voltage is preceded by a minus sign (−). Sometimes a positive voltage is preceded by a plus sign (+), or no sign at all. A number of voltages are relevant with regard to operating a memory cell, and are typically designated by the capital letter “V”, followed by another letter or letters. Some exemplary voltages of interest are:
   KeV short for kilo (thousand) electron volts
   Vt short for threshold voltage
   Vs short for source voltage
   Vd short for drain voltage
   Vg short for gate voltage
   Vbl short for bitline voltage. (the bitline may function as source or drain)
   Vwl short for wordline voltage (which typically is the same as Vg)
word line or wordline, (WL). A conductor normally connected to the gate of a memory cell transistor.
Work function The work function is the minimum energy (usually measured in electron volts) needed to remove an electron from a solid to a point immediately outside the solid surface. Here “immediately” means that the final electron position is far from the surface on the atomic scale but still close to the solid on the macroscopic scale. The work function is an important property of metals. The magnitude of the work function is usually about a half of the ionization energy of a free atom of the metal. The work function W of a metal is closely related to its Fermi energy level. “Work function” may also be defined as the energy difference between the vacuum level and the Fermi energy level. Semiconducting materials can also be characterized by work function.
write a combined method of first erasing a large set of bits, then programming a new data into the bit set.

### SUMMARY OF THE INVENTION

It is a general object of the invention to provide an improved FinFET memory device (or cell), and an improved method of operating the FinFET, including a plurality of FinFETs organized in a memory array.

Embedded DRAM or DRAM is difficult to scale due to requirement of a large capacitor. Zero-capacitor DRAM (Z-RAM) has been demonstrated by many (Innovative Silicon, TI, Infineon, Toshiba) as a promising mass application replacement. Charge is stored in the floating body in a Z-RAM cell, which affects device Vt and can be used to distinguish two states. However, a back gate is required to modulate charge stored in the body to improve retention time, which increases complexity while reducing scalability.

According to the invention, generally, a FinFET device is formed with two separated gates, both SOI (both are structures formed on the substrate), with one of the gates functioning as the back gate (a role normally performed by the substrate). The other of the two separated gates may be referred to as the front gate. This provides for easy back gate wiring, and stronger back gate control due to thinner oxide (instead of buried oxide, Tox>25 nm). The ability to form dual work function gates may increase retention time. The fin thickness may be >25 nm, to maintain a partially depleted body.

According to an embodiment of the invention, a FinFET device comprises: a fin structure having two side surfaces; a layer of oxide disposed on the two side surfaces; a first (“front”) gate structure disposed on one side of the fin, with the oxide therebetween; and a second (“back”) gate structure disposed on an opposite side of the fin, with the oxide therebetween. The fin structure may comprise a floating body of a volatile memory cell.

The first and second gate structures may be of the same polarity. The first and second gate structures may be of opposite polarity. The first and second gate structures may be biased oppositely.

According to an embodiment of the invention, a memory array comprises a plurality of FinFETs having dual, separate gates. Each FinFET has a front gate, and an individually-controllable back gate.

In one arrangement of a memory array, a front gate of a first FinFET (FF1) may be connected to a first word line (WL0); a body of the first FinFET (FF1) may be connected between a first bit line (BL0) and ground; and a back gate of the first FinFET (FF1) may be connected to a first erase bit line (EBL0) associated with the first bit line BL0. And, a front gate of a second FinFET (FF2) is connected to the first word line (WL0); a body of the second FinFET (FF2) is connected between a second bit line (BL1) and ground; and a back gate the second FinFET (FF2) is connected to a second erase bit line (EBL1) associated with the second bit line BL1.

In another arrangement of a memory array, a front gate of a first FinFET (FF1) is connected to a first word line (WL0); a body of the first FinFET (FF1) may be connected between a first bit line (BL0) and ground; a front gate of a second FinFET (FF2) may be connected to the first word line (WL0); a body of the second FinFET (FF2) may be connected between a second bit line (BL1) and ground; a back gate of the first FinFET (FF1) may be connected to an erase bit line (EBL0+1) associated with the first and second bit lines (BL0 and BL1); and a back gate of the second FinFET (FF2) may be connected to the erase bit line (EBL0+1) associated with the first and second bit lines (BL0 and BL1). And, the first and second FinFETs (FF1, FF2) may be adjacent FinFETs, connected back-to-back, with alternating left-right orientation, with both of their back gates being connected to the single, common erase bit line (EBL0+1).

### BRIEF DESCRIPTION OF THE DRAWINGS

Reference will be made in detail to embodiments of the disclosure, examples of which may be illustrated in the accompanying drawing figures (FIGs). The figures are intended to be illustrative, not limiting. Although the disclosure is generally described in the context of these embodiments, it should be understood that it is not intended to limit the disclosure to these particular embodiments.

Certain elements in selected ones of the figures may be illustrated not-to-scale, for illustrative clarity. The cross-sectional views, if any, presented herein may be in the form of “slices”, or “near-sighted” cross-sectional views, omitting certain background lines which would otherwise be visible in a true cross-sectional view, for illustrative clarity. In some cases, hidden lines may be drawn as dashed lines (this is conventional), but in other cases they may be drawn as solid lines.

If shading or cross-hatching is used, it is intended to be of use in distinguishing one element from another (such as a cross-hatched element from a neighboring un-shaded element. It should be understood that it is not intended to limit the disclosure due to shading or cross-hatching in the drawing figures.

Elements of the figures may (or may not) be numbered as follows. The most significant digits (hundreds) of the reference number correspond to the figure number. For example, elements of FIG. 1 are typically numbered in the range of 100-199, and elements of FIG. 2 are typically numbered in the range of 200-299. Similar elements throughout the figures may be referred to by similar reference numerals. For example, the element 199 in FIG. 1 may be similar (and possibly identical) to the element 299 in FIG. 2. Throughout the figures, each of a plurality of elements 199 may be referred to individually as 199a, 199b, 199c, etc. Such relationships, if any, between similar elements in the same or different figures will become apparent throughout the specification, including, if applicable, in the claims and abstract.

Throughout the descriptions set forth in this disclosure, lowercase numbers or letters may be used, instead of subscripts. For example Vg could be written V_{g}. Generally, lowercase is preferred to maintain uniform font size.) Regarding the use of subscripts (in the drawings, as well as throughout the text of this document), sometimes a character (letter or numeral) is written as a subscript—smaller, and lower than the character (typically a letter) preceding it, such as “Vₛ” (source voltage) or “H₂O” (water). For consistency of font size, such acronyms may be written in regular font, without subscripting, using uppercase and lowercase—for example “Vs” and “H₂0”.

Conventional electronic components may be labeled with conventional schematic-style references comprising a letter (such as A, C, Q, R) indicating the type of electronic component (such as amplifier, capacitor, transistor, resistor, respectively) followed by a number indicating the iteration of that element (such as “1” meaning a first of typically several of a given type of electronic component). Components such as resistors and capacitors typically have two terminals, which may be referred to herein as “ends”. In some instances, “signals” are referred to, and reference numerals may point to lines that carry said signals. In the schematic diagrams, the various electronic components are connected to one another, as shown. Usually, lines in a schematic diagram which cross over one another and there is a dot at the intersection of the two lines are connected with one another, else (if there is no dot at the intersection) they are typically not connected with one another.

FIG. 1 is a stylized cross-sectional view of a field effect transistor (FET), according to the prior art. To the left of the figure is a schematic symbol for the FET.

FIG. 2A is a stylized perspective view of a FinFET memory cell, according to the prior art. To the left of the figure is a schematic symbol for the FinFET memory cell.

FIG. 2B is a cross-sectional view of the FinFET memory cell of FIG. 2A, such as the device shown in FIG. 2A, taken on a line 2A-2A through the view of FIG. 2A, according to the prior art.

FIG. 3 is a diagram of a DRAM memory cell array, according to the prior art.

FIG. 4 is a cross-sectional diagram of a FinFET device, according to an embodiment of the invention. To the left of the figure is a schematic symbol for the FinFET device.

FIG. 5A is a cross-sectional diagram of a FinFET device, according to an embodiment of the invention. To the left of the figure is a schematic symbol for the FinFET device.

FIG. 6 is a diagram of an array architecture using FinFET devices for memory cells, according to an embodiment of the invention.

FIG. 7 is a diagram of an array architecture using FinFET devices for memory cells, according to an embodiment of the invention.

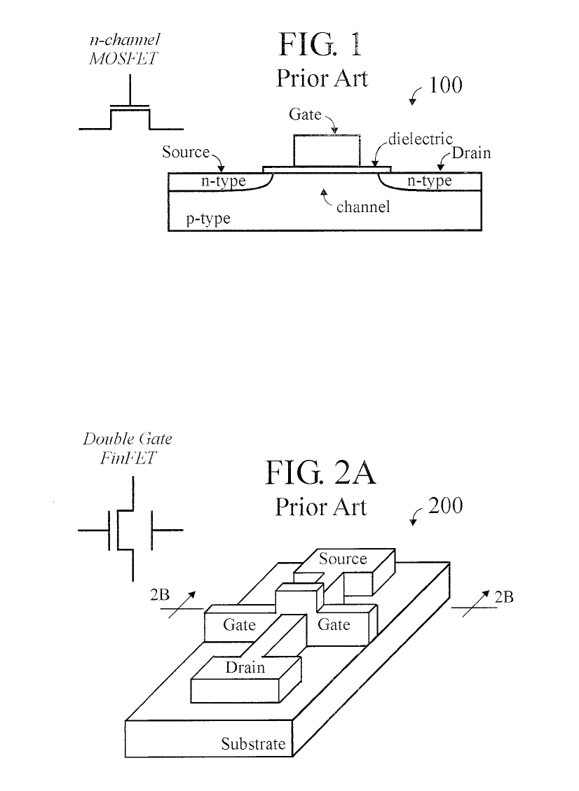

### DETAILED DESCRIPTION

In the following detailed description, numerous specific details are set forth in order to provide a thorough understanding of the disclosure. However, it will be understood by those skilled in the art that the teachings of the present disclosure may be practiced without these specific details. In other instances, well-known methods, procedures, components and circuits have not been described in detail so as not to obscure the teachings of the present disclosure.

Materials (such as silicon dioxide) may be referred to by their formal and/or common names, as well as by their chemical formula. Regarding chemical formulas, numbers may be presented in normal font rather than as subscripts. For example, silicon dioxide may be referred simply as “oxide”, chemical formula SiO2.

In the description that follows, exemplary dimensions may be presented for an illustrative embodiment of the teachings of the disclosure. The dimensions should not be interpreted as limiting. They are included to provide a sense of proportion. Generally speaking, it is the relationship between various elements, where they are located, their contrasting compositions, and sometimes their relative sizes that is of significance.

In the following detailed description, numerous specific details are set forth in order to provide a thorough understanding of the disclosure. However, it will be understood by those skilled in the art that the teachings of the present disclosure may be practiced without these specific details. In other instances, well-known methods, procedures, components and circuits have not been described in detail so as not to obscure the teachings of the present disclosure.

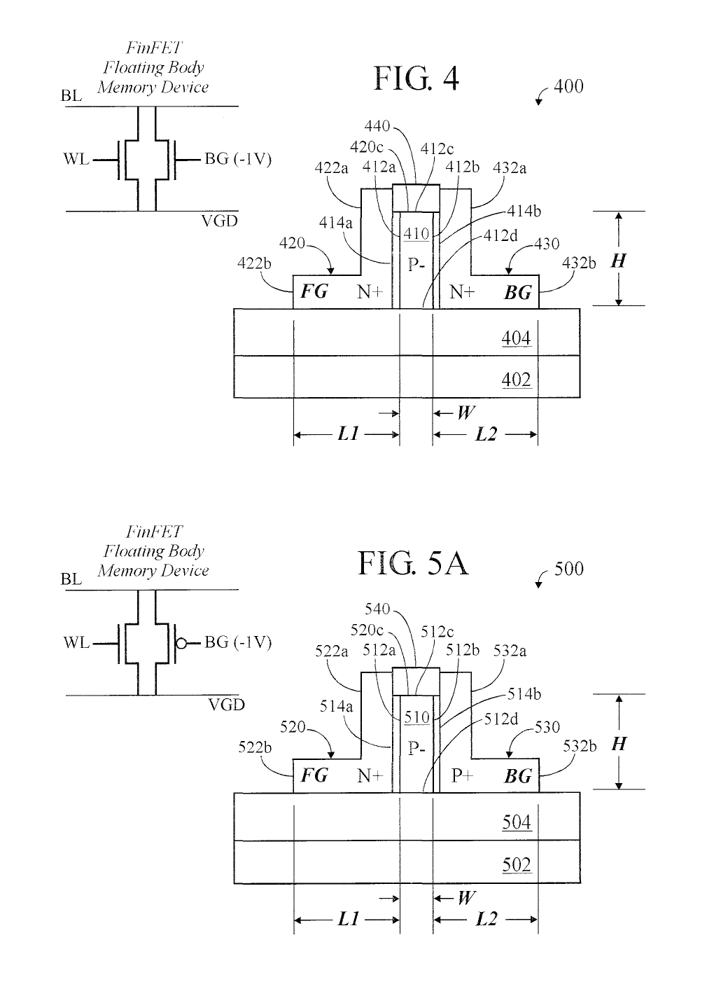

FIG. 4 illustrates a FinFET Floating Body Memory Device 400, according to an embodiment of the invention. The device 400 may be used as a volatile memory cell, generally in the manner of a DRAM. The device 400 may be formed using conventional SOI fabrication techniques. The schematic symbol next to the device indicates that the back gate (BG) is negatively-biased. Generally, the back gate (BG) may be biased opposite to the front gate (FG), to induce charges in the floating body.

A layer of oxide 404, such as buried oxide (BOX) having a thickness of 500-1000 Å(Angstroms) is disposed on a silicon substrate 402.

A silicon fin 410 is disposed atop the BOX 404, and forms the “floating body” of the device. The fin 410 may be an elongate (long, thin) structure, with a generally rectangular cross-section, having two opposite side surfaces 412a and 412b, a top edge surface 412c, and a bottom edge surface 412c opposite the top edge surface 412c. The fin 410 may have a width dimension “W”, (or thickness, as measured between its two side surfaces 412a and 412b) of approximately 20-60 nm, and a height dimension “H” (as measure between its top and bottom edge surfaces 412c and 412d) of approximately 30-100 nm. The fin 410 may be formed of monocrystalline silicon, epitaxially grown on the BOX layer 404.

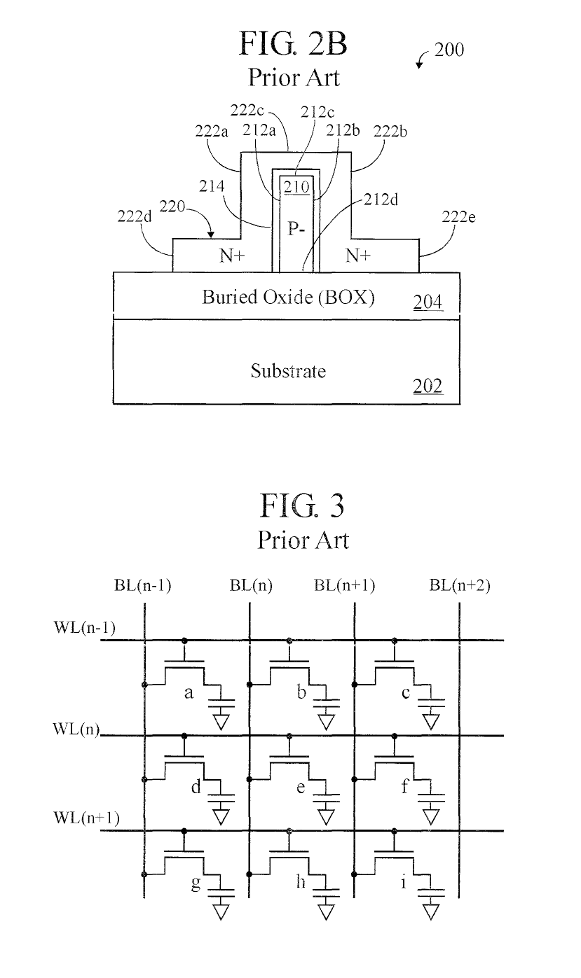

The fin 410 may have a length dimension “L” (not shown, into the page, as illustrated). The two ends (not shown) of the fin 410 may be enlarged, one end serving as the “source”, the other end serving as the “drain” of the device. Compare FIG. 2A.

The two sides surfaces 412a and 412b of fin 410 may be covered by a thin layer of oxide (generally “514”), such as thermal oxide, a portion 414a of which covers the left side edge 412a of the fin 410, a portion 414b of which covers the right side edge 412b of the fin 410. The oxide is shown as not covering the top edge surface 412c of the fin 410, but it may. The oxide 414 may have a thickness of approximately 1-3 nm. The oxide 414 functions as a gate oxide (gate dielectric). High K materials such as HfO2 or Ta2O5 may be used as gate dielectric.

A first gate structure 420 is formed on one side 412a of the fin 410, and may be referred to as the “front” gate (“FG”). (The front gate 420 is disposed on one side 412a of the fin 410, with the thin oxide 414 therebetween functioning in the role of gate oxide.) The front gate 420 is generally L-shaped, having a vertical (as viewed) portion 422a and a horizontal portion 422b extending from a bottom end (as viewed) end of the vertical portion 422a.

The vertical portion 422a may have a height substantially equal to, or slightly greater than, the height “H” of the fin 410, and may have a thickness of approximately 70-100 nm. The horizontal portion 422b may have a thickness substantially equal to the thickness of the vertical portion 422a.

The front gate 420 is disposed on the BOX layer 404, with its vertical portion 422a disposed substantially parallel to, and alongside of the side surface 412a of the fin 410, spaced therefrom by the thin oxide layer 414a surrounding the fin 410.

The front gate 420 may be formed of polycrystalline silicon, and may be doped to have a first polarity, such as N+.

A second gate structure 430 is formed on an opposite side 412b of the fin 410, and may be referred to as the “back” gate (“BG”). (The back gate 430 is disposed on an opposite side 412b of the fin 410, with the thin oxide 414 therebetween functioning in the role of gate oxide.) The back gate 420 is generally L-shaped, having a vertical (as viewed) portion 432a and a horizontal portion 432b extending from a bottom end (as viewed) end of the vertical portion 432a.

The vertical portion 432a may have a height substantially equal to, or slightly greater than, the height “H” of the fin 410, and may have a thickness of approximately 70-100 nm. The horizontal portion 432b may have a thickness substantially equal to the thickness of the vertical portion 432a.

The back gate 430 is disposed on the BOX layer 404, with its vertical portion 432a disposed substantially parallel to, and alongside of the side surface 412b of the fin 410, spaced therefrom by the thin oxide layer 414b surrounding the fin 410.

The back gate 430 may be formed of polycrystalline silicon, and may be doped to have a second polarity, such as N+, which is the same as the polarity (N+) of the front gate 420.

The front and back gates 420 and 430 are positioned approximately midway along the length of the fin 410 (compare FIG. 2A), and may have a longitudinal dimension (extending into the page, as illustrated).

Generally, a main difference between the FinFET 400 shown in FIG. 4A and the FinFET 300 shown in FIG. 3 is that rather than the gate being one piece and wrapping around the fin, the gate is divided (separated) into two pieces each of which (namely, the front gate and the back gate) can have a different (including opposite polarity) doping, each of which can individually be biased, and each of which can have a distinct work function. Regarding work function, this enables a high work function back gate for even smaller back gate bias. In this FinFET 400, the front and back gates 420 and 430 are distinct, individual structures, electrically independent from each other, and independently controllable.

An oxide structure 440 is disposed on the top surface 412c of the fin 410. Notice that the vertical portions 422a and 432a of the front and back gates 420 and 430 may extend above the height of the fin 410. The oxide structure 440 is disposed between top ends of the front and back gates 420 and 430, and physically separates them from one another.

Various features of the FinFET 400 may be described hereinbelow, with respect to the next embodiment of a FinFET 500.

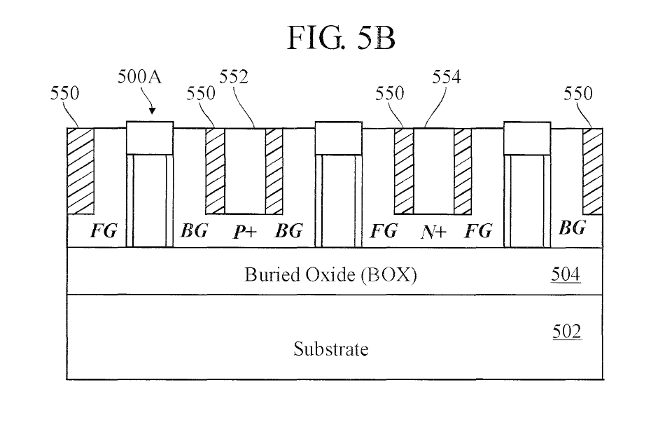

FIG. 5A illustrates a FinFET Floating Body Memory Device 500, according to an embodiment of the invention. The device 500 may be used as a volatile memory cell, generally in the manner of a DRAM. The device 500 may be formed using conventional SOI fabrication techniques. The schematic symbol next to the device indicates that the back gate (BG) is negatively-biased. Generally, the back gate (BG) may be biased opposite to the front gate (FG), to induce charges in the floating body.

A layer of oxide 504, such as buried oxide (BOX) having a thickness of 500-1000 Å (Angstroms) is disposed on a silicon substrate 502.

A silicon fin 510 is disposed atop the BOX 504, and forms the “floating body” of the device. The fin 510 may be an elongate (long, thin) structure, with a generally rectangular cross-section, having two opposite side surfaces 512a and 512b, a top edge surface 512c, and a bottom edge surface 512c opposite the top edge surface 512c. The fin 510 may have a width dimension “W” (or thickness, as measured between its two side surfaces 512a and 512b) of approximately 20-60 nm, and a height dimension “H” (as measure between its top and bottom edge surfaces 512c and 512d) of approximately 30-100 nm. The fin 510 may be formed of monocrystalline silicon, epitaxially grown on the BOX layer 504.

The fin 510 may have a length dimension “L” (not shown, into the page, as illustrated). The two ends (not shown) of the fin 510 may be enlarged, one end serving as the “source”, the other end serving as the “drain” of the device. Compare FIG. 2A. An effective channel length (Leff) is defined as the distance between the source and drain.

The two sides surfaces 512a and 512b of fin 510 may be covered by a thin layer of oxide (generally “514”), such as thermal oxide, a portion 514a of which covers the left side edge 512a of the fin 510, a portion 514b of which covers the right side edge 512b of the fin 510. The oxide is shown as not covering the top edge surface 512c of the fin 510, but it may. The oxide 514 may have a thickness of approximately 1-3 nm. The oxide 514 functions as a gate oxide (gate dielectric). High K materials such as HfO2 or Ta2O5 may be used as gate dielectric.

A first gate structure 520 is formed on one side 512a of the fin 510, and may be referred to as the “front” gate (“FG”). (The front gate 520 is disposed on one side 512a of the fin 510, with the thin oxide 514 therebetween functioning in the role of gate oxide.) The front gate 520 is generally L-shaped, having a vertical (as viewed) portion 522a and a horizontal portion 522b extending from a bottom end (as viewed) end of the vertical portion 522a.

The vertical portion 522a may have a height substantially equal to, or slightly greater than, the height “H” of the fin 510, and may have a thickness of approximately 70-100 nm. The horizontal portion 522b may have a length “L1” and a thickness substantially equal to the thickness of the vertical portion 522a.

The front gate 520 is disposed on the BOX layer 504, with its vertical portion 522a disposed substantially parallel to, and alongside of the side surface 512a of the fin 510, spaced therefrom by the thin oxide layer 514a surrounding the fin 510.

The front gate 520 may be formed of polycrystalline silicon, and may be doped to have a first polarity, such as N+.

A second gate structure 530 is formed on an opposite side 512b of the fin 510, and may be referred to as the “back” gate (“BG”). (The back gate 530 is disposed on an opposite side 512b of the fin 510, with the thin oxide 514 therebetween functioning in the role of gate oxide.) The back gate 520 is generally L-shaped, having a vertical (as viewed) portion 532a and a horizontal portion 532b extending from a bottom end (as viewed) end of the vertical portion 532a.

The vertical portion 532a may have a height substantially equal to, or slightly greater than, the height “H” of the fin 510, and may have a thickness of approximately 70-100 nm. The horizontal portion 532b may have a length “L2” and a thickness substantially equal to the thickness of the vertical portion 532a. The lengths “L1” and “L2” of the horizontal leg portions 522b and 532b need not be equal to one another.

The back gate 530 is disposed on the BOX layer 504, with its vertical portion 532a disposed substantially parallel to, and alongside of the side surface 512b of the fin 510, spaced therefrom by the thin oxide layer 514b surrounding the fin 510.

The back gate 530 may be formed of polycrystalline silicon, and may be doped to have a second polarity, such as P+, which is opposite to the polarity (N+) of the front gate 520.

The front and back gates 520 and 530 are positioned approximately midway along the length of the fin 510 (compare FIG. 2A), and may have a longitudinal dimension (extending into the page, as illustrated).

Generally, a main difference between the FinFET 500 shown in FIG. 5A and the FinFET 300 shown in FIG. 3 is that rather than the gate being one piece and wrapping around the fin, the gate is divided (separated) into two pieces each of which (namely, the front gate and the back gate) can have a different (including opposite polarity) doping, each of which can individually be biased, and each of which can have a distinct work function. Regarding work function, this enables a high work function back gate for even smaller back gate bias. In this FinFET 500, the front and back gates 520 and 530 are distinct, individual structures, electrically independent from each other, and independently controllable.

An oxide structure 540 is disposed on the top surface 512c of the fin 510. Notice that the vertical portions 522a and 532a of the front and back gates 520 and 530 may extend above the height of the fin 510. The oxide structure 540 is disposed between top ends of the front and back gates 520 and 530, and physically separates them from one another.

Generally, a main difference between the FinFET 500 shown in FIG. 5A and the FinFET 400 shown in FIG. 4 is that rather than the back gate being of the same polarity as the front gate, in the FinFET 500 the back gate is of opposite polarity to the front gate. Thus, whereas the FinFET 400 of FIG. 4 is substantially electrically symmetrical (the front and back gates could be functionally swapped with one another), the FinFET 500 of FIG. 5A is asymmetrical (the front and back gates cannot be functionally swapped with one another).

Some other features of the FinFET 500 may include, but are not limited to,
1. Thicker Si fin for partially depleted body but with intrinsic or lightly doped body for reduced Vt variation
2. Increased space between source/drain peak doped region to channel for longer retention time by limiting trap-assisted tunneling
3. Negatively biased back gate to collect excess holes from impact ionization
4. Thinner back gate oxide for reduced back gate bias and increased body coefficiency
5. High workfunction backgate for even smaller back gate bias
6. Optimized backgate oxide for desired leakage and capacitance considerations
7. The P+ back gate creates a high source-body potential barrier due to high work function
8. Increases the amount of holes accumulated along the back interface
9. Allows a lower Vbg to be used

There have thus been shown two examples of FinFETs with dual, separate gates. Both of the dual gates are structures formed on the substrate, stop buried oxide, using standard SOI fabrication techniques. This provides for easy back gate wiring, and stronger back gate control due to thinner oxide (instead of buried oxide, Tox>25 nm). The ability to form dual work function gates may increase retention time. The fin thickness may be >25 nm, to maintain a partially depleted body.

FIG. 5B shows three FinFETs 500A, 500B and 500C, such as the FinFET 500, disposed on a common substrate 502, atop a common BOX 504, such as for a row in an array architecture. The FinFETs 500A and 500C are oriented the same as each other, with their front gates (FG) to the left and their back gates (BG) to the right, and the FinFET 500B is oriented reverse, with its front gate (FG) to the right and its back gate (BG) to the left.

The back gates (BG) of the FinFETs 500A and 500B are facing each other, and oriented opposite to each other so that a continuous U-shaped structure is formed by the two oppositely-oriented L-shaped structures. The bottom legs of the back gates of the two FinFETs 500A and 500B are “common” with one another.

The front gates (FG) of the FinFETs 500B and 500C are facing each other, and oriented opposite to each other so that a continuous U-shaped structure is formed by the two oppositely-oriented L-shaped structures. The bottom legs of the front gates of the two FinFETs 500B and 500C are “common” with one another.

The FinFETs 500A, 500B, 500C are illustrative of a plurality (sequence, series, row) of FinFETs connected back-to-back (as well as front-to-front), and having alternating left-right orientation.

Dielectric material 550 is shown, filling spaces between the various FinFET structures. A first contact structure (the back gate (BG) contact) 552 is shown extending through the dielectric material 550 to the common bottom legs (both of which are back gate) of the two FinFETs 500A and 500B. A second contact structure (the front gate (FG) contact, or word line (WL) contact) 554 is shown extending through the dielectric material 550 to the common bottom legs (both of which are front gate) of the two FinFETs 500B and 500C.

### Memory Array Architectures

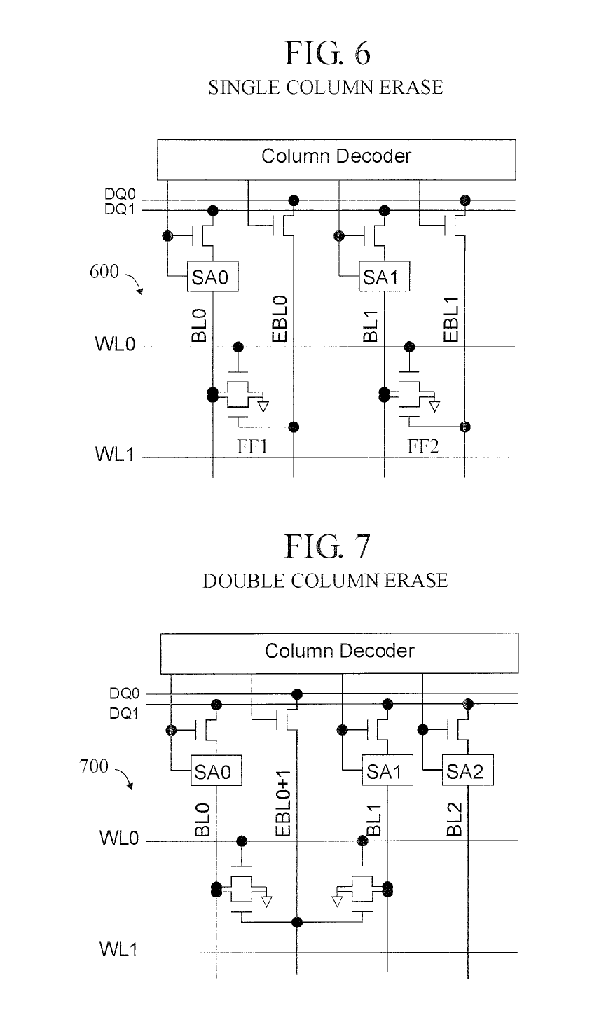

FIG. 6 illustrates an exemplary portion of a memory array 600, showing a two (of many) bit lines (BL0, BL1), two (of many) word lines (WL0, WL1), and a column decoder connected via conventional FETs, in a conventional manner and controlled by two (or many) data queue lines (DQ0, DQ1) to two (of many) sense amplifiers (SA)—for example, SA0 connected to BL0 and SA1 connected to BL1.

Two (of many) FinFETs (FF1, FF2) with floating body memory devices (cells) are connected between the bit lines (BL0, BL1) and the word lines (WL0, WL1), as illustrated. Each of the FinFETs (FF1, FF2) has a front gate, a back gate and a body, as described hereinabove. Source and Drain connections for each FinFET cell are shown (compare FIG. 2A).

A front gate of FF1 is connected to WL0. The body of FF1 is connected between BL0 and ground. The back gate of FF1 is connected to an erase bit line EBL0 associated with bit line BL0.

A front gate of FF2 is connected to WL0. (Since FF1 and FF2 are in the same row, they are connected to the same word line. FF1 and FF2 are in adjacent columns, so they are connected to different bit lines.) The body of FF2 is connected between BL1 and ground. The back gate of FF2 is connected to an erase bit line EBL1 associated with bit line BL1.

With this array architecture, a single column erase can be performed, erasing all of the memory cells connected to a given erase bit line, at once.

FIG. 7 illustrates an exemplary portion of a memory array 700, showing a two (of many) bit lines (BL0, BL1), two (of many) word lines (WL0, WL1), and a column decoder connected via conventional FETs, in a conventional manner and controlled by two (or many) data queue lines (DQ0, DQ1) to two (of many) sense amplifiers (SA)—for example, SA0 connected to BL0 and SA1 connected to BL1. A third bitline (BL1) and a third sense amplifier (SA2) are also shown in this figure.

Two (of many) FinFETs (FF1, FF2) with floating body memory devices (cells) are connected between the bit lines (BL0, BL1) and the word lines (WL0, WL1), as illustrated. Each of the FinFETs (FF1, FF2) has a front gate, a back gate and a body, as described hereinabove. Source and Drain connections for each FinFET cell are shown (compare FIG. 2A).

A front gate of FF1 is connected to WL0. The body of FF1 is connected between BL0 and ground. The back gate of FF1 is connected to an erase bit line EBL0+1 associated with bit lines BL0 and BL1.

A front gate of FF2 is connected to WL0. (Since FF1 and FF2 are in the same row, they are connected to the same word line. FF1 and FF2 are in adjacent columns, so they are connected to different bit lines.) The body of FF2 is connected between BL1 and ground. The back gate of FF2 is connected to the erase bit line EBL0+1 associated with bit lines BL0 and BL1.

With this array architecture, a double column erase can be performed, erasing all of the memory cells connected to a given erase bit line, at once. Notice that in this memory array 700, the two adjacent FinFETs (FF1, FF2) may be connected back-to-back, with alternating left-right orientation, such as was illustrated in FIG. 5B, with both of their back gates being connected to a single, common erase bit line (EBL0+1) which can be used for erasing the two adjacent FinFETs (FF1, FF2), and the entire columns of FinFETs which the FinFETs (FF1, FF2) represent. In contrast thereto, in the memory array 600 of FIG. 6, the two adjacent FinFETs (FF1, FF2) have the same orientation as one another, and no common connection other than sharing the same word line (WL0).

The memory array architectures described hereinabove are facilitated by the FinFETs described herein, each of which has a front gate, and an individually-controllable back gate.

Although the invention has been shown and described with respect to a certain preferred embodiment or embodiments, certain equivalent alterations and modifications will occur to others skilled in the art upon the reading and understanding of this specification and the annexed drawings. In particular regard to the various functions performed by the above described components (assemblies, devices, circuits, etc.) the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more features of the other embodiments as may be desired and advantageous for any given or particular application.

1. A FinFET device comprising:
a fin structure having two side surfaces, the fin structure having a thickness between its two side surfaces of 20-60 nm;
a layer of oxide disposed on the two side surfaces, the layer of oxide disposed on the two side surfaces of the fin functions as a gate oxide, and has a thickness of 1-3 nm:
a first (“front”) gate structure disposed on one side of the fin, with the oxide therebetween;
a second (“back”) gate structure disposed on an opposite side of the fin, with the oxide therebetween;
the fin structure comprising a floating body of a volatile memory cell formed using conventional SOI fabrication techniques;
the fin comprising monocrystalline silicon;
the first and second gate structures comprising polycrystalline silicon;
the device is disposed atop a buried oxide (BOX) layer on a substrate,
the BOX layer having a thickness of 500-1000 Å;
the first gate structure having a first polarity, and the second gate structure having a second polarity which is opposite to the polarity of the first gate structure: and
the first polarity is N+ and the second polarity is P+.

2-20. (canceled)
